(19) United States
(12) Patent Application Publication
(10) Pub. No.: US 2024/0065109 A1
(43) Pub. Date: Feb. 22, 2024

(54) METHOD FOR MANUFACTURING A MAGNETIC FIELD SENSOR CHIP WITH AN INTEGRATED BACK-BIAS MAGNET

(71) Applicant: Fraunhofer-Gesellschaft zur Förderung der angewandten Forschung e.V., München (DE)

(72) Inventors: Thomas LISEC, Itzehoe (DE); Björn GOJDKA, Itzehoe (DE); Hans-Peter HOHE, Erlangen (DE); Daniel CICHON, Erlangen (DE); Markus STAHL-OFFERGELD, Erlangen (DE)

(21) Appl. No.: 18/451,654

(22) Filed: Aug. 17, 2023

(30) Foreign Application Priority Data
Aug. 18, 2022 (DE) 102022208562.0

(51) Int. Cl. H10N 50/01; G01R 33/07; G01R 33/09

(52) U.S. Cl. CPC H10N 50/01; G01R 33/07; G01R 33/09

(57) ABSTRACT

A method for manufacturing a magnetic field sensor chip with an integrated back-bias magnet is described. A substrate with a first substrate surface and an opposite second substrate surface is provided, wherein at least one magnetic field sensor is arranged in a first substrate surface. A cavity is structured into the second substrate surface. The method involves generating the integrated back-bias magnet within the first cavity by introducing loose powder comprising a magnetic material into the first cavity and agglomerating the powder to a mechanically firm magnetic body structure by means of atomic layer deposition. According to the method, the step of generating the back-bias magnet is carried out temporally after the step of arranging the magnetic field sensor.

### CROSS-REFERENCE TO RELATED APPLICATION

This application claims priority from German Patent Application No. DE 10 2022 208 562.0, which was filed on Aug. 18, 2022, and is incorporated herein in its entirety by reference.

### BACKGROUND OF THE INVENTION

The innovative concept described herein concerns a miniaturized magnetic field sensor chip as well as a method for manufacturing a magnetic field sensor chip. The magnetic field sensor chip comprises a substrate having arranged thereon at least one magnetic field sensor. In addition, at least one back-bias magnet is integrated into the magnetic field sensor chip.

Magnetic field sensors are used in almost all technical fields. Compared to applications such as navigation and compass, which are based on the determination of the natural magnetic field of the earth, permanent magnets, whose magnetic field can be detected and whose relative position to the sensor may be monitored in this way, are used for the detection of movement, speed, or positions in equipment and devices. Alternatively, a soft-magnetic body, such as a gear wheel made of steel, may be monitored if a magnetic field is modulated through its movement.

This magnetic field, also called back-bias, is provided by a back-bias permanent magnet that is firmly connected to the sensor. Currently, conventionally manufactured permanent magnets whose dimensions exceed 1 mm and that are mounted, i.e. in a hybrid way, together with the sensor in the same housing are used for back-bias. Compared to the sensor elements that may be manufactured using a micro-structuring technique, the permanent magnet occupies the largest part of the housing.

In conventional magnetic field sensors, the active sensor areas (e.g. Hall plates) are arranged in a distance of 2 to 3 mm. Since the sensor areas should be in regions of the same magnetic field strength, the back-bias magnet has to be sufficiently wide to ensure this and to be able to compensate adjustment tolerances. Since the field strength additionally depends on the aspect ratio of the magnet, in case of a vertical magnetization, a certain minimum height of the magnet is simultaneously needed so as to provide a certain magnetic flux density in the region of the sensor areas.

DE 10 2011 114 773 B4 describes a method for miniaturizing the back-bias magnet. By using semiconductor technology methods, pyramid shapes are directly generated on the rear side of the sensor chip, e.g. by means of an isotropic etching, with a high positional accuracy. Subsequently, the magnet is manufactured on the substrate plane, e.g. by applying a polymer filled with magnetic particles. The magnetic field is additionally concentrated, or amplified, in the region of the sensor elements by means of a magnetic field concentrator on the front side, e.g. a planar coil with a core.

Manufacturing the back-bias magnet on the substrate level decreases the cost and increases the yield. For this reason, in EP 0 244 737 B1, a polymer layer filled with ferrite particles is applied to the planar substrate rear side and the substrate is subsequently diced into chips. After the chip has been glued into in the sensor housing and electrically contacted by means of wire bonding, a further magnet is generated on the top side of the chip by applying a polymer filled with ferrite particles.

The back-bias magnets generated on the substrate level may be shaped by applying the polymer filled with magnetic particles, e.g., by means of screen printing, as is described in EP 1 989 564 B1.

Instead of screen printing, US 2011 0 151 587 A1 uses a lacquer mask manufactured by means of lithographic methods of the semiconductor technology as a mold into which the polymer (magnetic paste) filled with magnetic particles is introduced, e.g., by means of doctoring. After the polymer has hardened, the lacquer mask is selectively removed again so that free-standing magnetic structures remain on the substrate surface.

The magnets generated on the substrate level enable space-efficient structures so that the corresponding magnetic field sensors may be used in very compact components. For devices as described in the above-mentioned US 2011 0 151 587 A1, e.g., catheters are mentioned as one possible field of application. However, by means of screen printing and doctoring, relatively flat magnetic structures may be manufactured precisely. However, since the strength of a magnet increases proportionally with its volume, such magnets may possibly not provide sufficiently strong magnetic fields for back-bias sensor arrangements.

Thus, it would be desirable to manufacture back-bias magnets that generate a sufficiently strong magnetic field despite a miniaturized structure, so as to be able to operate back-bias magnetic field sensors with them. In addition, it would be desirable that manufacturing of the back-bias magnets is cost efficient and simultaneously compatible with the generation of adjacent integrated sensor circuits.

### SUMMARY

An embodiment may have a method for manufacturing a magnetic field sensor chip with an integrated back-bias magnet, the method comprising: providing a substrate with a first substrate surface and an opposite second substrate surface, arranging at least one magnetic field sensor on the first substrate surface, structuring at least one first cavity into the second substrate surface, generating the integrated back-bias magnet within the first cavity by introducing loose powder comprising magnetic material into the first cavity and agglomerating the powder to a mechanically firm magnetic body structure by means of atomic layer deposition, wherein generating the back-bias magnet is carried out temporally after arranging the magnetic field sensor.

Another embodiment may have a magnetic field sensor chip with an integrated back-bias magnet manufactured by using the method according to the invention.

The object is solved with an inventive method for manufacturing a magnetic field sensor chip with an integrated back-bias magnet. A method step involves providing a substrate with a first substrate surface and an opposite second substrate surface. A further method step involves arranging at least one magnetic field sensor on the first substrate surface as well as structuring at least one first cavity into the second substrate surface. A further method step involves generating the integrated back-bias magnetic within the first cavity by introducing loose powder made of magnetic material into the first cavity, and agglomerating the powder to a mechanically firm magnetic body structure by means of atomic layer deposition. Due to the back-bias magnet being integrated on the same substrate that the magnetic field sensor is arranged on, the distance between the back-bias magnet and the magnetic field sensor may be reduced significantly compared to a hybrid assembly.

Through this, a very homogeneous magnetic field acts at the location of the sensor, and the magnetic field strength at the sensor is sufficiently large, despite the miniaturized back-bias magnet, to permeate the sensor. According to the invention, the step of generating the back-bias magnet is performed temporally after the step of arranging the magnetic field sensor.

In other words, the back-bias magnet may be generated temporally after the full realization of the magnetic field sensor, including optionally available integrated circuits, so that the manufacturing process of the magnetic field sensor, or of the circuits, is not restricted.

Advantageously, the cavity is introduced into the substrate by means of micro-structuring techniques, e.g. by means of an etching process. These micro-structuring techniques can be controlled very precisely so that a position of a cavity in the substrate may be determined with an accuracy in the range of micrometers. Through this, the back-bias magnet to be generated within the cavity may be aligned highly precisely with respect to the magnetic field sensor. A further advantage of the cavities manufactured in micro-structuring techniques is that cavities with different geometric shapes may be realized with a very high precision. Accordingly, the back-bias magnets generated in the correspondingly shaped cavities comprise such a highly-precise geometric shape. For example, such a geometric shape may be selected such that it may selectively influence the course of the magnetic field lines of the back-bias magnets. For example, the magnetic field line may be influenced such that as homogenous and/or concentrated as possible a magnetic flux through the magnetic field sensor takes place. Thus, application-specific “shaping” of the magnetic field may be realized.

In addition, the present invention concerns a magnetic field sensor chip with an integrated back-bias magnet manufactured using the above-described method.

### BRIEF DESCRIPTION OF THE DRAWINGS

Embodiments of the present invention will be detailed subsequently referring to the appended drawings, in which:

FIGS. 1A-1G show schematic views of different magnetic field sensors with back-bias magnets according to the known technology,

FIGS. 2A-2C show a schematic view of individual method steps for manufacturing an inventive magnetic field sensor chip according to an embodiment,

FIGS. 3A-3C show a schematic view of individual method steps for manufacturing an inventive magnetic field sensor chip according to a further embodiment,

FIGS. 4A-4C show schematic illustrations for generating inventive micro-body structures by agglomeration of loose particles using an ALD method according to embodiments of the invention,

FIG. 5A shows a perspective view of a measurement arrangement with an inventive magnetic field sensor chip 200 and a soft-magnetic transmitter wheel,

FIG. 5B shows an exemplary waveform of the measured magnetic field components in the x, y and z direction,

FIG. 6A shows a schematic view of an inventive magnetic field sensor chip with an annular integrated back-bias magnet according to an embodiment,

FIG. 6B shows a schematic view of an inventive magnetic field sensor chip with individual integrated back-bias magnets according to an embodiment,

FIGS. 7A-7B show a schematic view of an inventive magnetic field sensor chip with an annular integrated back-bias magnet and soft-magnetic micro-cores according to an embodiment, and

FIG. 8 shows a schematic view for visualizing the effects of time-controlled etching processes with respect to the structured cavities and the micro-body structures and back-bias magnets to be generated therein.

### DETAILED DESCRIPTION OF THE INVENTION

In the following, embodiments are described in more detail with respect to the drawings, wherein elements with the same or similar function are provided with the same reference numerals.

Method steps illustrated or described in the context of the present disclosure may be carried out in any other sequence than the one that is illustrated or described. In addition, method steps concerning a specific feature of an apparatus are interchangeable with the same feature of the apparatus and vice versa.

If this disclosure refers to a compensation, in particular a compensation of process-caused differences of magnetic field characteristics of individual back-bias magnets, this is to be understood as a weakening, or reduction, of measurement deviations to be attributed to the different magnetic field characteristics. Thus, a compensation described herein is a weakening, or reduction, of a measurement error caused by the magnetic field characteristics that differ for process-related reason (compared to identical magnetic fields). The term compensation can be understood as a reduction of the measurement error to a deviation of s 10%, or up to a full reduction, or cancellation, of the measurement error.

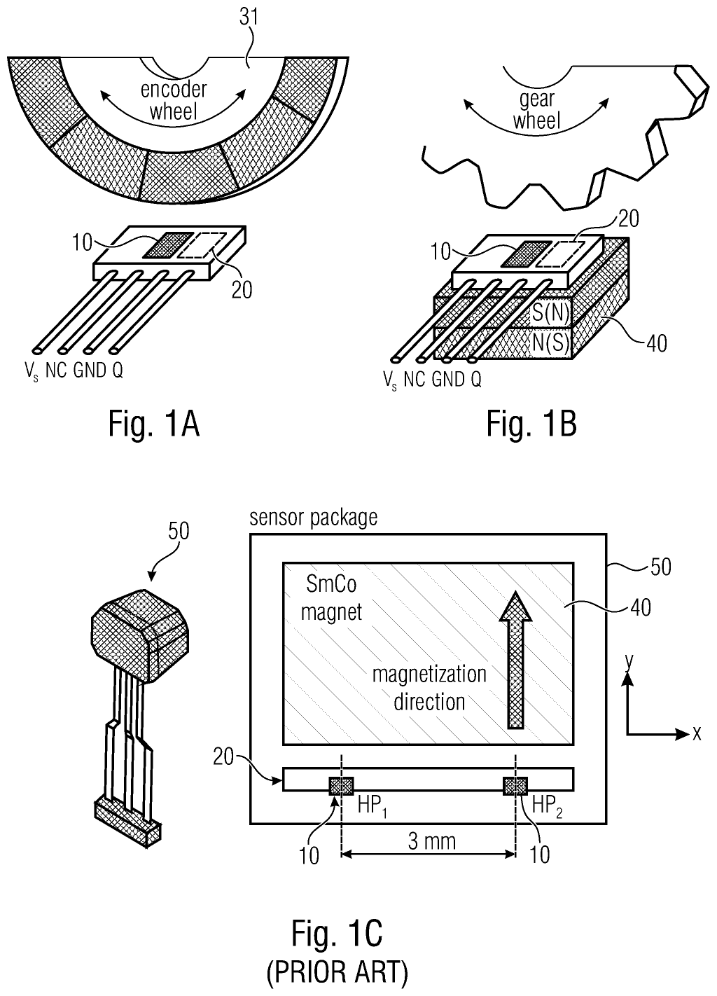

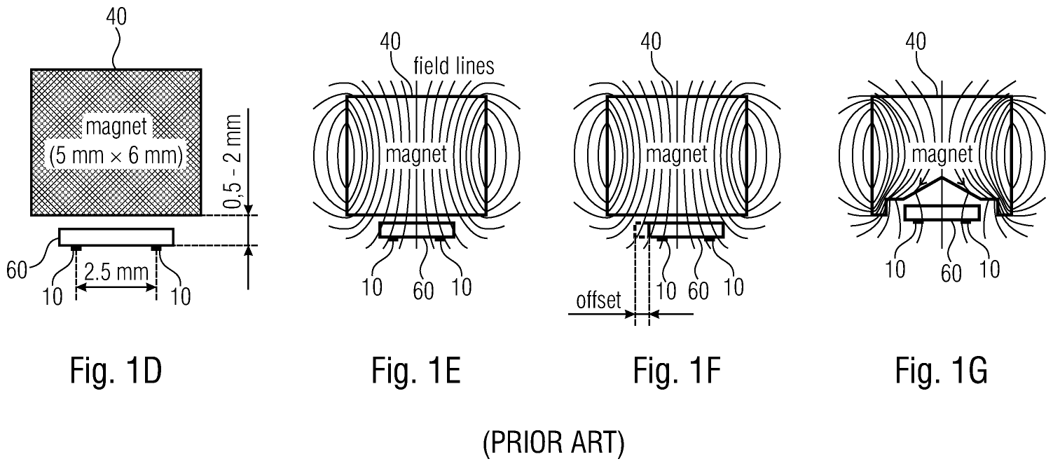

Initially, conventional magnetic field sensors according to the know technology and their fields of application will be described. To this end, reference is made to FIGS. 1A to 1G.

FIG. 1A show a schematic illustration of the measurement of the rotational speed of an axis by means of a Hall sensor 10, including an associated sensor circuit 20, in combination with an encoder wheel 31. FIG. 1B shows the same measurement, however, by means of a Hall sensor 10 with a back-bias magnet 40 in combination with a soft-magnetic transmitter wheel (or sensor wheel) 32.

FIGS. 1A and 1B therefore illustrate the use of magnetic field sensors 10 using the example of monitoring a rotational movement. A sensor 10 in combination with an encoder wheel 31 with oppositely magnetized pole fields, as illustrated in FIG. 1A [1], makes it possible to precisely determine the axial position, rotational angle, and rotational speed.

In the case of a sensor 10 with a back-bias magnet 40 (FIG. 1B), a (soft-magnetic) gear wheel 32 present in the transmission is monitored instead of the encoder wheel 31. The movement of the teeth causes a periodic modulation (e.g. distortion) of the field provided by the back-bias magnetic 40, which is detected by the sensor 10. The accuracy of the positional determination is indeed lower than in the case of the encoder wheel 31, however, the gear wheel 32 (FIG. 1B) also costs significantly less than that an encoder wheel 31 (FIG. 1A).

FIG. 1C shows a sensor package 50 with a Hall sensor 10 and a back-bias magnetic 40 arranged in the package 50. The illustrated schematic cross-section (on the right side) shows that the magnetic 40 occupies the largest part of the housing, or the package, 50. The Hall sensor circuit 20 has two active sensor areas (Hall plates) 10 with a distance of 3 mm that should be in regions of equal magnetic field strength. Thus, the back-bias magnet 40 has to be sufficiently wide to ensure this and, in addition, to be able to compensate adjustment tolerances.

Since the field strength depends on the aspect ratio of the magnet 40, in case of a vertical magnetization, a certain minimum height is simultaneously needed to be able to provide a certain magnetic flux density in the region of the sensor areas 10.

Since the back-bias magnets 40 used here typically consist of material such as SmCo or NdFeB, their size accordingly calls for large amounts of valuable resources (rare earth metals). To reduce the amounts, smaller magnets could be used instead of large magnets. However, in this case, the costs do not only rise due to an increased assembly effort. Manufacturing very small magnets made of SmCo or NdFeB with edge lengths of below 1 mm becomes increasingly elaborate and expensive. Micro-magnets manufactured by means of precision laser treatment are known. They are offered at small batch prices of approximately 10 euros per piece [4], however, which is a disproportionately high-cost effort for a large batch production.

In addition, there is a discrepancy between the size of the back-bias magnet 40 and the size of the active sensor area, which is below 100 μm×100 μm in the case of Hall sensors, and in the range of 10 μm×10 μm in the case of magneto-resistive xMR sensors (e.g. AMR, GMR, TMR, etc.), and therefore smaller by two orders of magnitude. Since most modern devices, such as drones or robots, consist of ever more compact mechanisms and components, a device according to FIG. 1C cannot just lead to problems with respect to space, but also to functional impairments, e.g. through crosstalk of the magnetic field of the back-bias magnet 40 with respect to adjacent electronic components. To use such devices in ever more miniaturized systems for detecting movements, speeds, or positions in an optimum and resource-friendly way, the back-bias magnet 40 should be substantially miniaturized.

However, miniaturization of the back-bias magnets 40 has another disadvantage. The smaller the back-bias magnets 40, the weaker their magnetic field. In addition, the smaller back-bias magnets 40 are obviously able to provide a homogeneous field course across a correspondingly small area only. This will be briefly explained with reference to the drawings 1D to 1G.

As is illustrated in FIG. 1D, the back-bias magnet 40 is usually on the rear side of a semiconductor chip 60 with the sensor element 10 on its front side. The distance between the back-bias magnet 40 and the sensor element 10 is selected such that the magnetic field strength in the region of the sensor elements 10 does not lead to them being overdriven, and at the same time, the modulation of the magnetic field by the rotating gear wheel can still be measured well. The dimensions exemplarily stated in FIG. 1D refer to a gear wheel with teeth having a width of 3 mm and a distance of 1 mm to 4 mm between the gear wheel and the sensor chip 60. The remanence of the back-bias magnets 40 is typically around 1 tesla.

FIG. 1E illustrates the course of the magnetic field lines in an arrangement according to FIG. 1D. Since, due to the position, x and y components of the magnetic field significantly vary in the plane of the sensor element 10, a precise adjustment of the back-bias magnet 40 symmetrically with respect to the y axis is needed with respect to the sensor chip 60. In conventional assembly methods, the offset may easily be in the range of 0.5 mm to 1 mm.

As is illustrated in FIG. 1F, the two sensor elements 10 of the chip 60 are then exposed to very different magnetic fields, which may cause a significant offset, and, in the case of magneto resistive sensor elements (AMR, GMR, etc.) may even lead to the entire sensor arrangement being overdriven.

As is exemplary shown in FIG. 1G, the course of the field lines in the region of the sensor chip 60 may be optimized (e.g. aligned vertically) by means of a special geometric shaping of the magnet 40, allowing to increase assembly tolerances. However, manufacturing such specially shaped magnets causes additional costs. Regardless, the assembly, or adjustment, ultimately remains disproportionately elaborate, since the magnet 40 still has to be aligned comparably precisely with respect to the sensor elements 10.

The present invention provides a solution for the above-mentioned problems. In particular, the inventive method described here allows to manufacture micro-magnets that can be placed extremely close to the sensor elements. This ensures that, despite the miniaturized dimensions of the inventive micro-magnets, a sufficiently strong magnetic field permeates the sensor elements. In addition, the inventive method enables a highly-precise orientation of the micro-magnet with respect to the sensor elements.

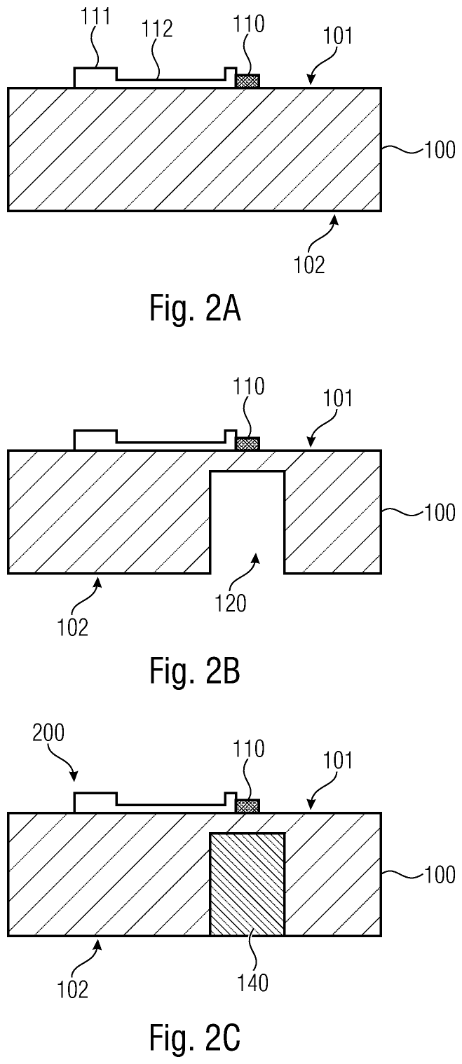

FIG. 2A to 2C shows a first embodiment of the inventive method for manufacturing a magnetic field sensor chip with an integrated back-bias magnet, wherein the individual steps of the method are described on the basis of structural components.

FIG. 2A first shows a substrate 100. For example, this may be a silicone substrate. For example, substrates made of glass, ceramics, or plastic would also be conceivable. The substrate 100 comprises a first substrate surface 101 and an opposite second substrate surface 102.

At least one magnetic field sensor 110 is arranged on the first substrate surface 102. For example, this may be a Hall sensor or a magneto-resistive sensor, wherein this type of sensors may also be referred to as xMR sensors. Optionally, contact pads 111 may be realized on the first substrate surface 101 so as to contact the magnetic field sensor 110 by means of corresponding connection lines 112.

The contact pads 111 schematically indicated here may symbolize a circuit that contains magnetic field sensors 110 and is manufactured by known semiconductor technologies. Mostly, it does not only contain the contact pads 111 but also active, analog, and digital circuit components for conditioning and evaluating signals.

As can be seen in FIG. 2B, at least one cavity 120 is generated in the second substrate surface 102. For example, this cavity 120 may be structured into the second substrate surface 102 by means of micro-structuring techniques. For example, the cavity 120 may be generated by means of reactive ion etching (RIE), or deep reactive ion etching (DRIE).

Anticipating FIG. 2C, a back-bias magnet 140 is later generated in this cavity 120. Thus, it makes sense to generate the cavity 120 in the region of the magnetic field sensor 110. In the embodiment shown here, the cavity 120 is generated exactly opposite to the magnetic field sensor 110. The magnetic field sensor 110 comprises an active sensor region. Advantageously, the cavity 120 may therefore be generated in particular opposite to such an active sensor region. However, other arrangements are possible, which will be described later on.

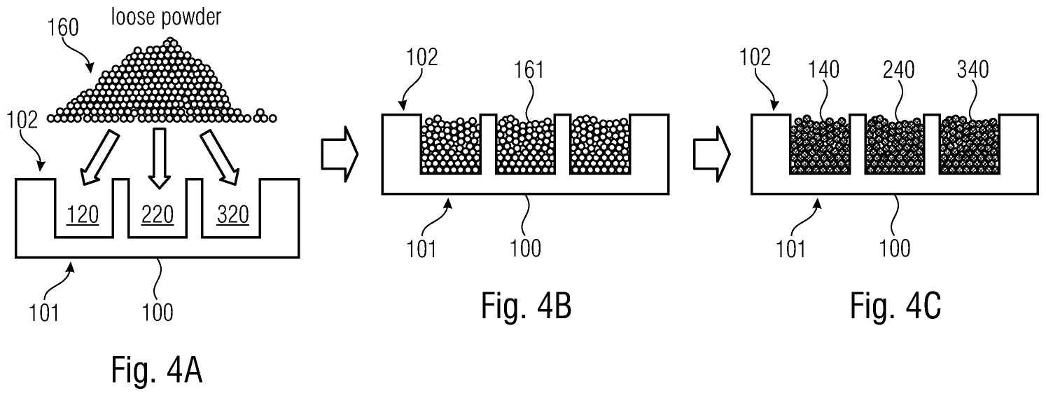

As can be seen in FIG. 2C, a back-bias magnet 140 is generated within the cavity 120. Advantageously, the back-bias magnet 140 fully fills the cavity 120 and is accordingly located at precisely the same location where the cavity 120 was located before. Generating the back-bias magnet 140 by using the inventive method will later be described with reference to FIGS. 4A to 4C in more detail.

Since the back-bias magnet 140 is generated in the cavity 120 structured in the substrate 100, it is an integrated back-bias magnet 140, i.e. the back-bias magnet 140 is integrated in the same substrate 100 the magnetic field sensor 110 is arranged on. Consequently, the magnetic field sensor chip 200 with the integrated back-bias magnet 140 schematically illustrated in FIG. 2C is created. This differs from the previously known hybrid structures in which the back-bias magnet and the sensor are each configured as separate components.

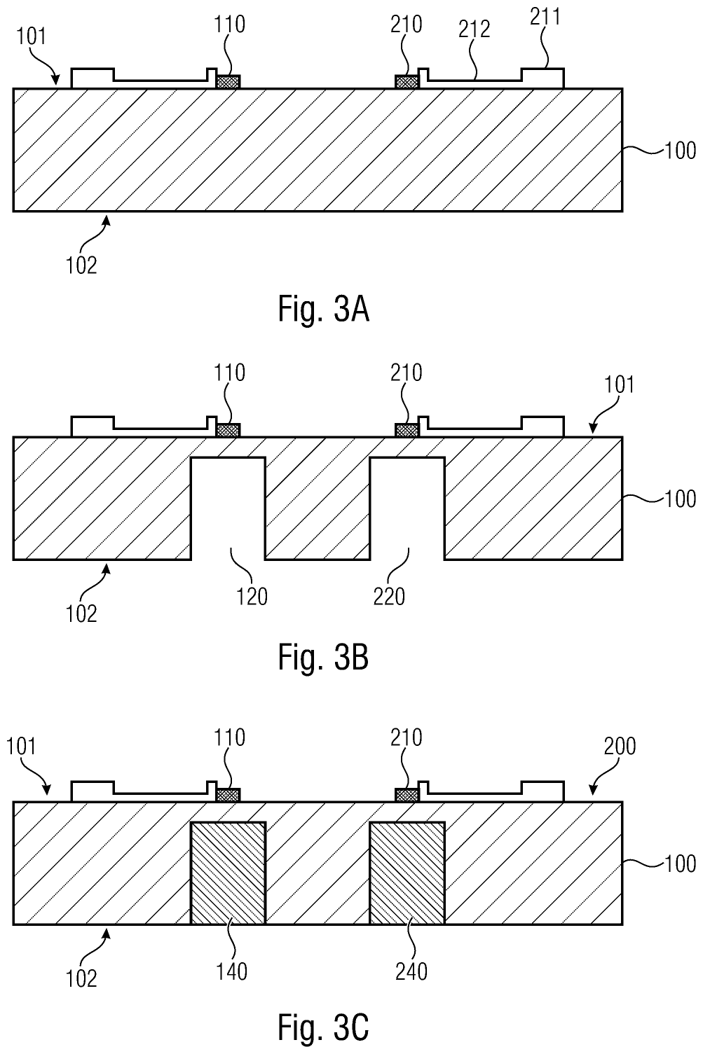

First, reference is made to FIGS. 3A to 3C, which show a further conceivable embodiment of a magnetic field sensor chip 190 that may be manufactured with the inventive method described herein. Same components with same or similar functions as described with reference to FIGS. 2A to 2C are provided with the same reference numerals. Thus, only the differences compared to FIGS. 2A to 2C are described in the following.

In FIG. 3A, an additional second magnetic field sensor 211 is arranged on the first substrate surface 101. The same is purely representative for a possible multitude of magnetic field sensors 110, 210, . . . that may be present. Optionally, corresponding contact pads 211 may also be realized here on the first substrate surface 101 to contact the second magnetic field sensor 210 by means of corresponding connection lines 212.

As can be seen in FIG. 3B, a second cavity 220 is generated in the second substrate surface 102. For example, this second cavity 220 may be structured into the second substrate surface 102 by using micro-structuring techniques. For example, the second cavity 120 may be generated by means of reactive ion etching (RIE) or deep reactive ion etching (DRIE).

Later on, a second back-bias magnet 240 is generated in this second cavity 220. Thus, it makes sense to generated the second cavity 220 in the region of the second magnetic field sensor 210. In the embodiment shown here, the second cavity 220 is generated precisely opposite to the second magnetic field sensor 210. The second magnetic field sensor 210 comprises an active sensor region. Advantageously, the second cavity 220 may be generated in particular opposite to such an active sensor region.

As can be seen in FIG. 3C, a second back-bias magnet 240 is generated within the second cavity 220. Advantageously, the second back-bias magnet 240 fully fills the second cavity 220 and is accordingly located at the exact position where the second cavity 220 was located before.

Since the back-bias magnets 140, 240 are generated in the cavities 120, 220 structured in the substrate 100, they are integrated back-bias magnets 140, 240, i.e. the back-bias magnets 140, 240 are integrated in the same substrate 100 the magnetic field sensors 110, 210 are arranged on as well. As a result, the magnetic field sensor chip 200 with integrated back-bias magnets 140, 240 schematically illustrated in FIG. 3C is created. The same differs from previously known hybrid structures in which the back-bias magnet and the sensor are each configured as separate components.

If several (i.e. at least two) magnetic field sensors 110, 210 are provided, at least one back-bias magnet 140, 240 may be assigned to each of these magnetic field sensors 110, 210. Other embodiments in which more than one back-bias magnet 140 is assigned to a magnetic field sensor 110 are also conceivable and will be described later.

FIGS. 4A to 4C show in purely schematic way how back-bias magnets 140, 240, 340 may be generated within the respective cavity 120, 220, 320 by using the inventive method. In FIGS. 4A to 4C, a previously described substrate 100 can be seen. In contrast to FIGS. 2A to 3C, however, the substrate 100 is rotated by 180°. Several, e.g. here three, cavities 120, 220, 320 have been structured into the second substrate surface 102. For clarity reasons, the above-described magnetic field sensors 110 are not illustrated on the first substrate surface 101.

First, a loose powder 160 made of magnetic material is filled into the cavities 120, 220, 320. The powder 160 comprises has particles 161 made of magnetic material in an amount of more than 50%. This may be hard-magnetic material or soft-magnetic material. The individual particles 161 may have a particle size in the range of micrometers.

After filling the cavities 120, 220, 320 with the loose powder 160, the particles 161 are agglomerated into a mechanically firm magnetic body structure by means of adapted atomic layer deposition (ALD) specially adjusted. That is, the previously loose particles 161 are now joined into a mechanically firm structure and form the previously described back-bias magnets 140, 240, 340. Exactly one back-bias magnet 140, 240, 340 is formed in each filled cavity 120, 220, 340.

The sole purpose of FIGS. 4A to 4C is the schematic description of the generation of the back-bias magnets 140, 240, 340 in the cavities 110, 210, 310. For simplicity reasons, the above-mentioned magnetic field sensors 110, 210 are not illustrated here. However, at least one magnetic field sensor 110 is arranged on the first substrate surface 101. For example, it would be conceivable that one respective magnetic field sensor 110, 210, . . . would be provided per each back-bias magnet 140, 240, 340.

One advantage of using the above-described method for generating the back-bias magnets 140, 240, 340 is that the integrated 3D micro-structures, i.e. the integrated back-bias magnets 140, 240, 340, may be manufactured from any magnetic powder materials, including the use of compositions of different materials. A composition of particles 161 of different sizes of one and the same material may also be used so as to maximize the filling density of the micro-magnets 140, 240, 340 and to therefore increase their remanence. While, a filling density of up to 64% may be achieved for a uni-disperse ball-shaped powder 160, a filling density of up to 87% is possible for a mixture of small and large particles 161 with a size ratio of 1:10 [8].

The inventive method provides an uncomplicated and cost-efficient possibility for manufacturing magnetic 3D micro-structures, i.e. integrated back-bias magnets 140, on planar substrates 100, e.g., made of silicone, glass, ceramics, or plastic, as well as the possibility for combining these micro-structured back-bias magnets 140, 240, 340 with magnetic field sensors 110, 210 on one and the same substrate 100.

In the simplest case, a silicone substrate 100 with completely processed circuits comprising magneto-resistive sensors or Hall sensors may be provided with hard-magnetic 3D micro-structures (micro-magnets) 140, 240, 340 by performing the above-described agglomeration method on the rear side 102 of the substrate 100.

According to the invention, the step of generating the at least one back-bias magnet 140 is performed temporally after the step of arranging the magnetic field sensor 110. That is, the micro-magnets 140, 240, 340 may be generated after fully having realized the magnetic field sensors 110, 210 so that the manufacturing process of the magnetic field sensors 110, 210 is not restricted. This is an advantage of the present invention since the method described herein is compatible with the so-called Back-End-of-Line (BEOL), the second part of the semi-conductor process that follows the manufacturing of transistors and that mainly includes the realization of multilayer re-wirings made of metal such as AL and Cu as well as dicing the semi-conductor substrate into chips. To generate the back-bias magnets 140, 240, 340 by using the above-described agglomeration method by means of ALD, high process temperatures of 500° C. are not required, which would destroy the integrated circuits and/or magnetic field sensors 110, 210. Thus, the magnetic field sensors 110 including integrated circuits may be fully manufactured first, including the multilayer re-wirings, and, subsequently, prior to dicing into chips, the micro-structured back-bias magnets 140 may be generated.

In addition to the above-mentioned BEOL compatibility, the inventive method has another advantage. That is, the cavities 120, 220 may be created in a highly precise way, i.e. the cavities 120, 220 may be aligned precisely so that the field lines of the back-bias magnets 140, 240 generated in the cavities 120, 220 permeate as homogenously as possible. In order words, the cavities 120, 220 (and therefore also the back-bias magnets generated therein) may be placed very precisely at a desired position relative to the magnetic field sensor 110. This is significantly less complicated than hybrid structures in which the back-bias magnets have to be aligned and mounted with respect to these sensors.

Due to this precise positioning of the integrated back-bias magnets 140, it is possible to generate a magnetic field with a desired magnetic field characteristic at the magnetic field sensors 110. For example, if the integrated back-bias magnet 140 is arranged opposite an active sensor region of the magnetic field sensor 110, the magnetic field generated by the back-bias magnet 140 acts only perpendicular to the chip surface, i.e. perpendicular to the first and second substrate surface 101, 102, respectively. In this case, reference is also made to a magnetic field directed in the Z direction.

For example, the magnetic field sensor 110 may be configured in the form of a so-called 3D Hall sensor. The same is configured to detect magnetic field vectors in all three spatial directions. To this end, e.g., the 3D Hall sensor 110 may comprise three Hall elements, wherein each Hall element is sensitive for a respective spatial direction, i.e. an X Hall element, a Y Hall element, and a Z Hall element may be provided.

If, as mentioned above, a magnetic field acts perpendicular to the chip surface (i.e. in the Z direction) at the location of the active sensor region, the Z Hall element measures the full field, whereas the X Hall element and the Y Hall element do not measure any field.

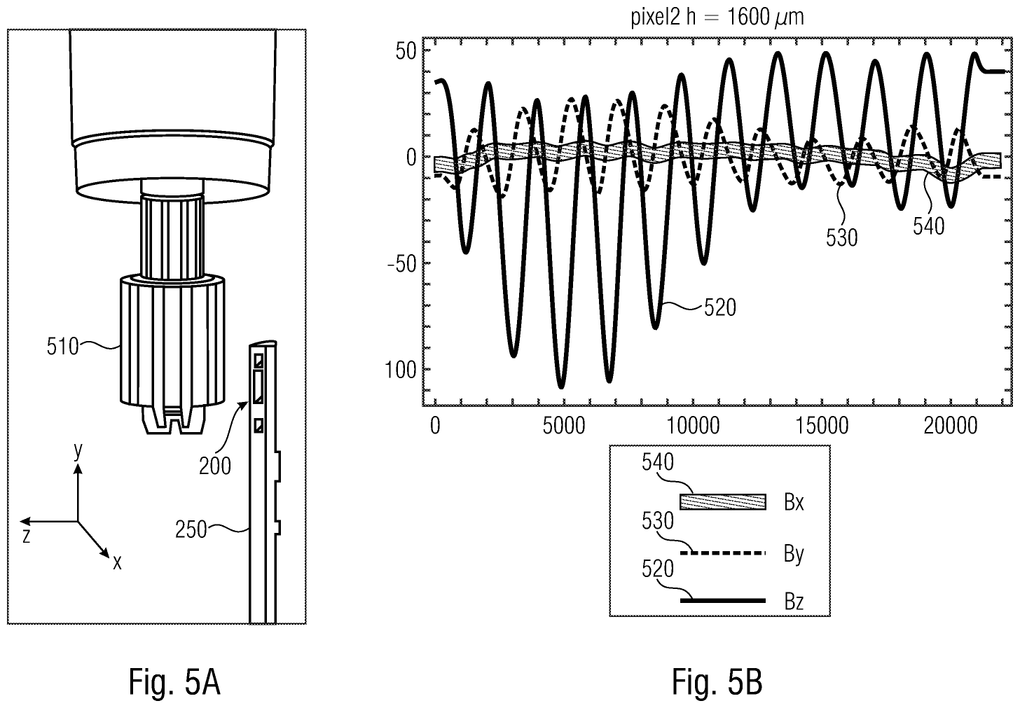

FIGS. 5A and 5B show a corresponding example of an inventive magnetic field sensor chip 200 arranged on a board 250. The magnetic field sensor chip 200 comprises a magnetic field sensor (here not explicitly shown) and an integrated back-bias magnet arranged opposite to the magnetic field sensor. If a (magnetic) transmitter 510 rotates in front of the magnetic field sensor chip 200, this can be seen very clearly on the basis of the Z component 520 (FIG. 5B), i.e. the Z Hall element registers a great deflection. The (magnetic) transmitter 510, e.g. as illustrated in FIG. 5A, may be a magnetized gear wheel that is otherwise non-magnetic. However, it may be a permanently magnetized component, such as a permanent magnet.

Due to the above-mentioned arrangement of the integrated back-bias magnet 140, a very strong static magnetic field, i.e. the base magnetic field of the back-bias magnet 140, overlaps the magnetic field component in the Z direction. (Note: the base field cannot be seen in FIG. 5B since the offset has been raised). Thus, the magnetic sensor 110 would have a rather unfavorable signal-to-noise ratio (SNR) in the Z direction.

On the other hand, in this example, the Y Hall element would not see any magnetic field in its sensitivity direction if the transmitter 510 (e.g. the gear wheel) is not present. It is only through the presence of the transmitter 510 that the magnetic field is deflected and a field component in the sensitivity direction (here: the Y direction) can be measured. In this case, the corresponding signal 530 of the Y Hall element may be output with significantly less noise than the signal 520 of the Z Hall element, since the base field of the back-bias magnet 140 only acts in the Z direction and accordingly does not comprise any Y component. In other words, the base field of the back-bias magnet 140 does not overlap the Y component 530 to be measured in this case. In FIG. 5B, the Y component 530 has a lower amplitude than the Z component 520. However, without the overlapping base field, the sensor signal 530 of the Y Hall element can be amplified significantly.

In addition, the X component 540 may be used as a type of track guidance. If the transmitter 510 (e.g. gear wheel) is centrally placed, the X Hall element does not see any field. If the transmitter 510 is not centrally placed, an X component 540 is created, which the X Hall element is able to measure. The above-stated advantages can be realized with the inventive integrated back-bias magnets 140, since the assembly tolerances are precise enough in this case. This can virtually not be realized with a hybrid structure.

As briefly mentioned in the beginning, the cavities 120, 220 in which the back-bias magnets 140, 240 are generated may be generated by using micro-structuring methods. To this end, e.g., the so-called deep reactive ion etching (DRIE, also referred to as Bosch-process) may be used. The cavities 120 generated in a silicone substrate, and accordingly also the micro-magnets 140 generated therein, may have any geometries in the lateral direction. Several magnets 140 may also be assigned to one sensor element 110, since the above-described method enables manufacturing of back-bias magnets 140 with a structural width of between 25 μm and 2000 μm [7].

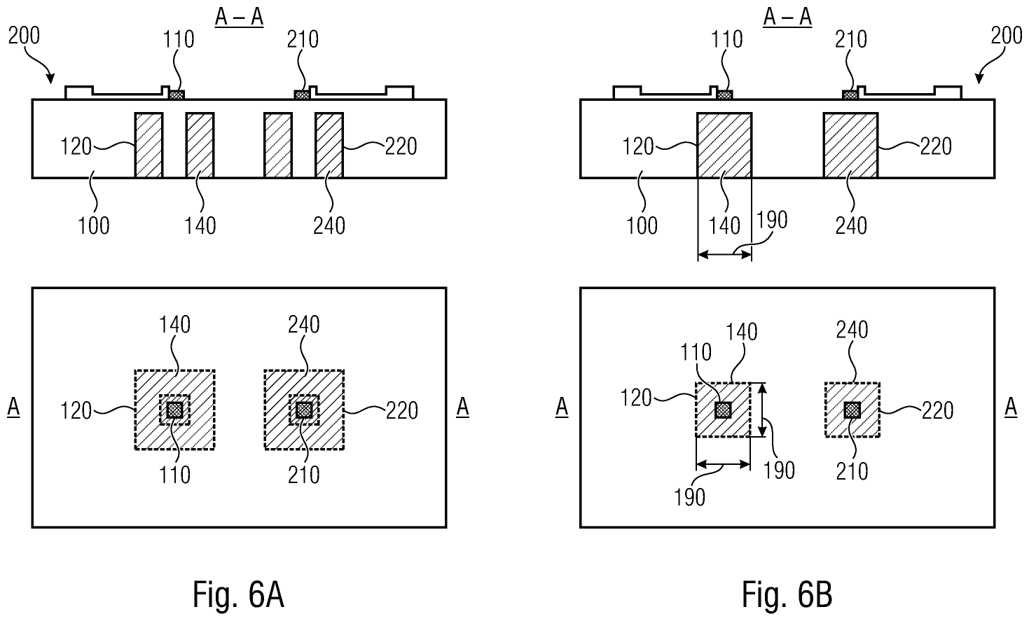

That is, a cavity 120 may be generated such that it has a lateral expansion of between 25 μm and 2000 μm so that the back-bias magnet 140 generated therein is configured as a micro-magnet having a structural width of between 25 μm and 2000 μm. Corresponding embodiments are subsequently described in more detail with reference to FIGS. 6A and 6B. Here, one substrate 100 each is shown with a completely processed circuit, wherein the circuit comprises magnetic field sensors 110, 210 in the form of magneto-resistive sensors or Hall sensors, as well as contact pads 111, 211. Micro-magnets 140, 240 with different geometries are embedded on the rear side 102 of the substrate 100.

In the upper illustration, FIG. 6A shows a schematic cross-section through an inventive magnetic field sensor chip 200 with two annular back-bias magnets 140, 240. In the lower illustration, a corresponding top view of the magnetic field sensor chip 200 is shown. Subsequently, the corresponding methods steps for manufacturing the magnetic field sensor chip 200 are described using the example of the first cavity 120 and the first back-bias magnet 140 generated therein, as well as using the example of the first magnetic field sensor 110. This description also applies to the second cavity 220 shown here and the second back-bias magnet 240 generated therein, as well as to the second magnetic field sensor 210. This description also applies to further cavities as well as further back-bias magnets and further magnetic field sensors not shown here.

According to FIG. 6A, the step of structuring the first cavity 120 involves that the first cavity 120 is structured into the substrate 100 in the form of a trench structure. In the top view (FIG. 6A, bottom), it can be seen that this trench structure extends around an active sensor region of the magnetic field sensor 110, so that the back-bias magnet 140 generated in the first cavity 120 ultimately also extends around the active sensor region of the magnetic field sensor 110.

As can be seen in the top view, the trench structure 120 is configured so as to be annular, i.e. the first cavity 120 is generated in the form of an annular trench structure that is closed in itself and extends to its full extent around the active sensor region of the magnetic field sensor 110. In other words, seen in the top view, the active sensor region of the magnetic field sensor 110 is arranged within the annular trench structure 120.

Alternatively, it would be conceivable that the first cavity 120 is configured in the form of an annular trench structure with discontinuation. That is, the first cavity 120 may comprise several discontinuous trench structure segments. These, as is illustrated in FIG. 6A, may again be arranged around the active sensor region of the magnetic field sensor 110.

By using the annular embodiments discussed with reference to FIG. 6A, it is possible to generate at the location of the active sensor region a magnetic field without a Z component. That is, in this embodiment, the magnetic field sensor 110 does not measure any Z component of the static magnetic field of the back-bias magnet 140. Through this, the signal-to-noise ratio (SNR) may be increased significantly.

FIG. 6B shows a further embodiment of an inventive magnetic field sensor chip 200, wherein a schematic cross-section is again shown in the upper illustration, and a corresponding top view of the magnetic field sensor chip 200 is shown in the lower illustration.

This implementation essentially corresponds to the embodiment discussed previously with reference to FIG. 3C, which is why a repeated description of the respective elements is omitted here.

However, the previously mentioned structural width, or lateral expansion, is plotted in FIG. 6B, denoted with reference numeral 190. This is the lateral expansion of the cavity 120 in the substrate plane. The lateral expansion may concern the expansion in a first lateral direction (e.g. along the length of the substrate 100), and the expansion in a second lateral direction (e.g. along the width of the substrate 100). This naturally also applies to the back-bias magnet 140 generated in the cavity 120. Essentially, it may have the same structural width, or lateral expansion, as the cavity 120.

That is, the first cavity 120 may be generated such that it comprises a lateral expansion 190 of between 25 μm and 2000 μm so that the back-bias magnet 140 generated therein may be configured as a micro-magnet comprising a structural width 190 of between 25 μm and 2000 μm.

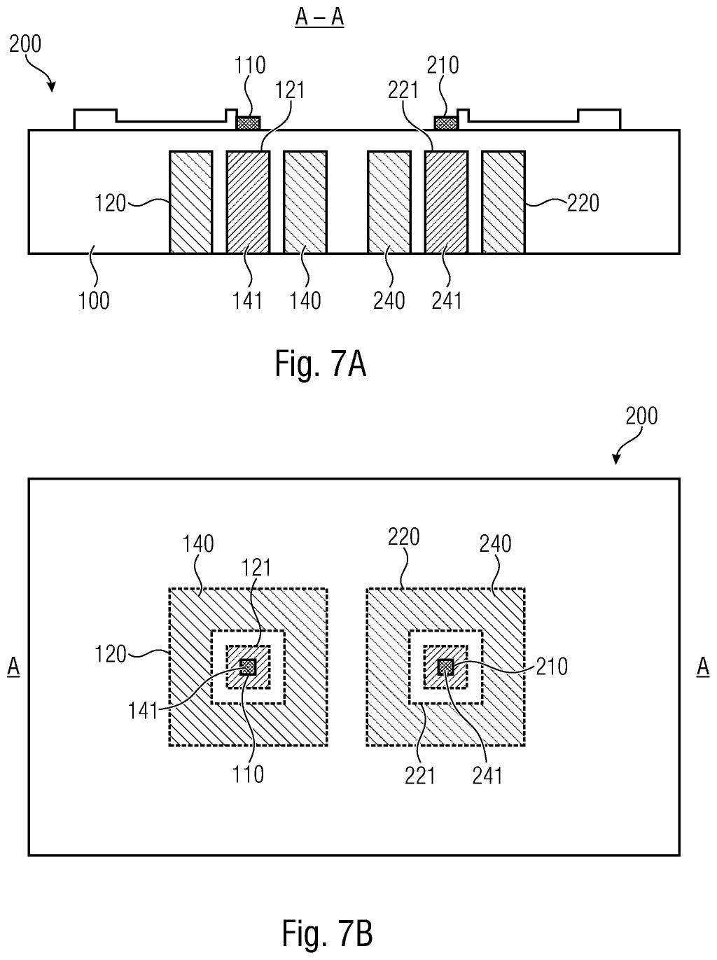

In addition, it is possible to combine hard-magnetic and soft-magnetic 3D micro-structures so as to optimally shape the magnetic field in the active sensor region. FIGS. 7A and 7B show a corresponding embodiment in which a hard-magnetic 3D micro-structure, i.e. a micro-structured back-bias magnetic 140, surrounds a soft-magnetic 3D micro-body structure 141 arranged opposite to the sensor 110. In this case, e.g., the soft-magnetic 3D micro-structure 141 may act like a core in the interior of the annular back-bias magnet 140. Thus, the soft-magnetic 3D micro-body structure 141 may also be referred to as a micro-core.

To manufacture the magnetic field sensor chip 200 shown here, e.g., after generating the micro-structured back-bias magnet 140, e.g. made of NdFeB powder according to FIGS. 4A to 4C, the same procedure may be performed again, however, with a soft-magnetic powder material, such as Fe or NiFe. Subsequently, this will be described in more detail with reference to FIGS. 7A and 7B.

FIG. 7A shows a schematic cross-section through an inventive magnetic field sensor chip 200 with two annular back-bias magnets 140, 240, each surrounding an additional 3D micro-body structure 141, 241. FIG. 7B shows a corresponding top view of the magnetic field sensor chip 200. The subsequent description refers to the first magnetic sensor 110, the first cavity 120, the first additional cavity 121, as well as the first annular back-bias magnetic 140 and the first additional 3D micro-body structure 141. However, the same applies for the second and further corresponding elements 210, 220, 221, 240, 241 shown here.

In this embodiment, in addition to the first cavity 120, an additional cavity 121 is structured into the second substrate surface 102. Similar as in FIG. 6A, here, the first cavity 120 is configured in the form of a (closed or discontinuous) annular trench structure extending around the active sensor region of the magnetic field sensor 110, i.e. the active sensor region is arranged within the annular first cavity 120 in a top view (FIG. 7B).

The above-mentioned additional cavity 121 is, in a top view, generated on one of the two substrate surfaces 101, 102 (cf. FIG. 7B), within the annular first cavity 120. Thus, the additional cavity 121 is surrounded by the annular first cavity 120. For example, the additional cavity 121 may be structured opposite to the magnetic field sensor 110 so that this additional cavity 240 is opposite to the active sensor region of the magnetic field sensor 110.

In a next step, a 3D micro-body structure may be generated in the additional cavity 121. To this end, the above-described method may again be use, i.e. the additional cavity 121 may be filled with a loose powder 160 made of magnetic material which is subsequently agglomerated by means of ALD. In contrast to generating the hard-magnetic back-bias magnet 140, however, this may be a soft-magnetic material, i.e. the additional cavity 121 may be filled with a loose powder 160 comprising a soft-magnetic material, and may be subsequently solidified by means of ALD. Through this, a soft-magnetic 3D micro-body structure 141 that is surrounded by the hard-magnetic back-bias magnet 140 and that may be referred to as a micro-core due to its properties may be generated within the additional cavity 121.

In a top view of one of the two substrate surfaces 101, 102 (cf. FIG. 7B), the active sensor region of the magnetic field sensor 110 and the micro-core 141 generated in the additional cavity 121 overlap. That is, the additional micro-core 141 integrated into the substrate 100 is arranged opposite to the active sensor region of the magnetic field sensor 110. Through this, the magnetic field generated by the annular back-bias magnetic 140 may be shaped particularly advantageously so a field distribution in the active region as possible is as homogenous as possible.

As is the case for all cavities described herein, the additional cavity 141 may be generated by using micro-structuring techniques, such as DRIE etching. As is well known, the etching rate of a dry etching process varies across the substrate area so that, in the case of DRIE (Bosch process), there are deeper cavities in the middle of the wafer than at the edge.

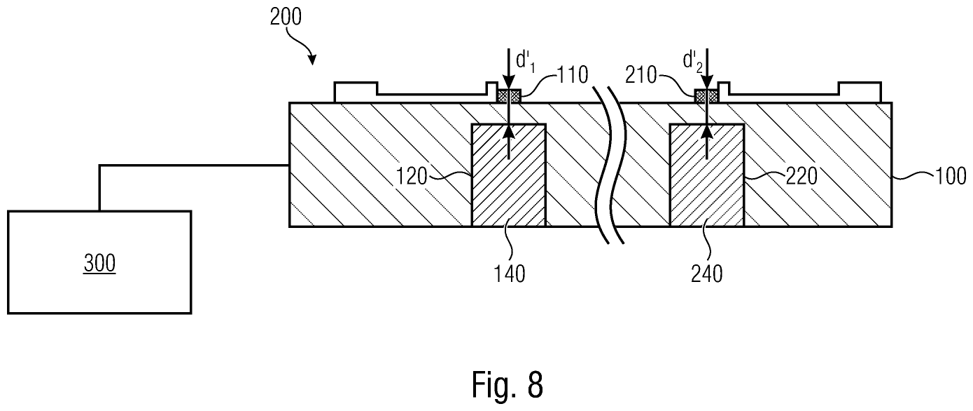

As is illustrated in FIG. 8A, in the case of a time-controlled etching process, the distance d′₁ between the magnetic field sensor 110 and the cavity 120 in the middle of the wafer is significantly smaller than the distance d′₂ between the magnetic field sensor 210 and the cavity 220 at the edge of the wafer. At the same time, the volume of the micro-magnets 140, 240 generated in the respective cavities 120, 220 is different, i.e. the inner magnet 140 (with respect to the wafer area) has in this case a larger volume than the outer magnet 240.

Naturally, this causes a variation of the respective magnetic field characteristics leading to measurement deviations between the respective magnetic field sensors 110, 210.

According to the invention, such variations, or measurement deviations, between two (or more or several) magnetic field sensors 110, 210 may be corrected or compensated, by measures on the circuit level. Thus, according to the inventive method, a compensation circuit 300 configured to drive the magnetic field sensor chip 200 such that measurement deviations caused by process-related different magnetic field characteristics are able to be compensated is provided.

According to further embodiments, the compensation circuit 300 may alternatively or additionally be configured to reduce, or compensate, other measurement deviations that are caused by other interference variables. For example, the compensation circuit 300 may be configured to compensate the single-phase offset of the magnetic field sensor 110. The compensation circuit 300 may also be used to balance, or compensate, measurement deviations that are caused by the above-described process tolerances.

Since, according to the invention, the back-bias magnet 140 is integrated in the same substrate 100 as the magnetic field sensor 110, there is a further advantage with respect to measurements. Due to the integration in the same substrate 100 and due to the high thermal conductivity of silicon, the back-bias magnet 140 has the same temperature as the magnetic field sensor 110. In magnetic field sensors 110 using the CMOS technique, such as Hall sensors, the temperature may be measured with corresponding circuits. In a case of a known temperature of the magnet, the temperature-dependent field strength of the back-bias magnet 140 may be corrected. Again, this is only possible with integrated magnets. According to embodiments of the invention, the compensation circuit 300 is configured to compensate the measurement deviations that are caused by a temperature-dependent change of the magnetic field of the back-bias magnet 140.

Since, in addition to the magnetic field sensor 110 with the back-bias magnet 140 arranged behind the same, further sensors may be arranged on the magnetic field sensor chip 200 (without further additional back-bias magnets), these additional sensors may be used to differentiate the transmitter field of the back-bias magnet 140 from interference fields. In an exemplarily realized prototype, the magnetic field sensor 110 with a back-bias magnet 140 arranged directly opposite to the same measures a field strength of approximately 75 mT. A second sensor spaced apart by 2 mm without its own back-bias magnet only measures 2 mT thereof. That is, the second sensor may detect external interference fields almost independently of the effective magnetic field of the back-bias magnet 140. This also becomes possible since, according to the invention, the miniaturized back-bias magnet 140 is integrated into the substrate and can therefore be positioned highly precisely so that its magnetic field almost exclusively permeates the associated magnetic field sensor 110.

According to corresponding embodiments of the invention, at least one second magnetic field sensor is provided in addition to the magnetic field sensor 110, wherein this second magnetic field sensor is mostly arranged outside of the effective magnetic field of the back-bias magnet 140. This is to be understood such that the additional magnetic field sensor is arranged in a region with only <10% of the maximum field strength of the back-bias magnet 140 (in the Z direction, i.e. perpendicular to the chip plane).

Accordingly, the compensation circuit 300 may be configured to compensate the interference field detected by the additional magnetic field sensor by subtracting the corresponding interference field magnitude from the signal of the first magnetic field sensor 110.

It applies for all of cavities described herein that the cavities are structured in the substrate 100 in such a way that they extend from the second substrate surface 102 towards the first substrate surface 101. In this case, the cavities are structured into the substrate 100 until almost reaching the first substrate surface 101. That is, the cavities are structured into the substrate 100 to such a depth that the cavities are located as close as possible to the first substrate surface 101 and therefore as close as possible to the magnetic field sensors 110, 210 arranged on the first substrate surface 101. Through this, as little a distance as possible can be achieved between the magnetic field sensors 110, 210 and the magnets or micro-body structures, generated in the respective cavities.

The inventive method described herein provides a possibility for manufacturing cost-efficient miniaturized magnetic field sensors with an integrated back-bias magnet for detecting movement, speed or position in different equipment and devices. For the purpose of miniaturization of such components, it is proposed to manufacture micro-structured magnets that are located closer to the sensor compared to hybrid structures, by integrating them into the chip, and that enable an application-specific “shaping” of the magnetic field.

Among others, the inventive method, as well as the magnetic field sensor chip 200 that may be manufactured with this method, have the following advantages.
Significant reduction of the structural size of up to one order of magnitude allows to use such devices in particularly compact electronic systems.
Reduction of costs through material savings, in particular rare earth metals, and simplified manufacturing/assembly process.
Novel sensor arrangements, or systems, that could not have been realized so far can now be developed.
New possibilities to reduce process tolerances, thermally induced drift effects or magnetic interference fields by means of appropriate compensation circuits.

The method described herein provides a sensor arrangement, consisting of an integrated circuit with one or several magnetic field sensors and one or several magnetic 3D micro-structures assigned to the magnetic field sensors and located in cavities on the rear side of the same silicon substrate.

Generating the cavities on the rear side of the substrate and manufacturing the magnetic 3D micro-structures may be carried out after completion of the integrated circuit.

Manufacturing the magnetic 3D micro-structures by means of agglomeration of particles of a hard or soft-magnetic powder material in the range of μm may be carried out by means of atomic layer deposition.

To this end, the use of a powder material with special size distribution is proposed so as to increase the filling density of the micro-magnets and therefore to increase their remanence.

In addition, the use of compositions made of different powder materials is proposed so as to adapt the magnetic properties of the micro-magnets.

In addition, a combination of soft-magnetic and hard-magnetic 3D micro-structures is proposed, which are arranged directly adjacent, or assigned to a magnetic field sensor, to shape the magnetic field in the sensor area, or in the area of the target.

The above-described embodiments merely represent an illustration of the principles of the present invention. It is understood that other persons skilled in the art will appreciate modifications and variations of the arrangements and details described herein. This is why it is intended that the invention be limited only by the scope of the following claims rather than by the specific details that have been presented herein by means of the description and the discussion of the embodiments.

Even though some aspects have been described within the context of a device, it is understood that said aspects also represent a description of the corresponding method, so that a block or a structural component of a device is also to be understood as a corresponding method step or as a feature of a method step. By analogy therewith, aspects that have been described within the context of or as a method step also represent a description of a corresponding block or detail or feature of a corresponding device.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

### BIBLIOGRAPHY

[1] https://www.rutronik.com/suppliers/infineon/3d-magnetic-sensors/
[2] https://www.allegromicro.com/en/Insights-and-Innovations/Technical-Documents/Hall-Effect-Sensor-IC-Publications/AN296157-ATS344-Magnetically-Back-Biased-Differential-Linear-Sensor-IC
[3] file:///C:/Daten/Home %20Lisec/Patente/Partikel+ALD/15%20-%20Integriertes %20BackBias %20f % C3% BCr %20Hall-Sensoren %20IIS/Literatur/Allegro %20ATS344-Datasheet.pdf
[4] https://audemars.com/micro-magnets-manufacturing/
[5] T. Lisec, O. Behrmann, B. Gojdka, “PowderMEMS—A generic microfabrication technology for integrated three-dimensional functional microstructures”, Micromachines 2022, 13(3)
[6] M. T. Bodduluri, T. Lisec, L. Blohm, F. Lofink, B. Wagner, “High-performance integrated hard magnets for MEMS applications”, Proceedings of MikroSystemTechnik Kongress 2019, Berlin, 28.-30. October 2019
[7] T. Lisec et al., “Integrated high power micro magnets for MEMS sensors and actuators. Proceedings of Transducers 2019, Berlin, Germany, 23.-27. June 2019
[8] T.-S. Yang et al., “Fabrication and characterization of parylene-bonded Nd—Fe—B powder micromagnets”, J. Appl. Phys. 109, 07A753 (2011); doi: 10.1063/1.3566001

1. Method for manufacturing a magnetic field sensor chip with an integrated back-bias magnet, the method comprising:
providing a substrate with a first substrate surface and an opposite second substrate surface,
arranging at least one magnetic field sensor on the first substrate surface,
structuring at least one first cavity into the second substrate surface,
generating the integrated back-bias magnet within the first cavity by introducing loose powder comprising magnetic material into the first cavity and agglomerating the powder to a mechanically firm magnetic body structure by means of atomic layer deposition,
wherein generating the back-bias magnet is carried out temporally after arranging the magnetic field sensor.

2. Method according to claim 1,
wherein structuring the first cavity involves that the first cavity is generated opposite to an active sensor region of the magnetic field sensor so that the back-bias magnet generated in the first cavity ultimately is also opposite to the active sensor region.

3. Method according to claim 1,
wherein structuring the first cavity involves that the first cavity is structured into the substrate in the form of a trench structure,
wherein, in a top view of one of the two substrate surfaces, this trench structure extends around an active sensor region of the magnetic field sensor so that the back-bias magnetic generated in the first cavity ultimately also extends around the active sensor region.

4. Method according to claim 3,
wherein the first cavity is generated in the form of an annular trench structure that is closed in itself and extends to its full extent around the active sensor region.

5. Method according to claim 3, further comprising:
structuring an additional cavity into the second substrate surface so that the additional cavity is opposite to the active sensor region of the magnetic field sensor and, in a top view of one of the two substrate surfaces, is surrounded by the first cavity, and
filling the additional cavity with a magnetic material.

6. Method according to claim 5,
wherein filing the additional cavity with the magnetic material involves that the magnetic material is filled into the additional cavity in the form of a loose powder, wherein the method further comprises:
agglomerating the powder to a mechanically firm micro-body structure by means of atomic layer deposition.

7. Method according to claim 5,
wherein the loose powder to be filled into the additional cavity comprises mostly, i.e. to more than 50%, of a soft-magnetic material.

8. Method according to claim 1,
wherein the loose powder to be filled into the first cavity comprises mostly, i.e. to more than 50%, of a hard-magnetic material.

9. Method according to claim 1,
wherein the loose powder to be filled into the first cavity comprises a composition of particles of different sizes with a size ratio of at least 1:10.

10. Method according to claim 1,
wherein the magnetic field sensor is configured as a Hall sensor, or
wherein the magnetic field sensor is configured as a magneto-resistive sensor.

11. Method according to claim 1,
wherein the first cavity is generated such that it comprises a lateral expansion of between 25 μm and 2000 μm so that the back-bias magnet generated therein is configured as a micro-magnet comprising a structural width of between 25 μm and 2000 μm.

12. Method according to claim 1, further comprising:
structuring at least one second cavity into the second substrate surface and generating at least one second back-bias magnetic in this second cavity,
wherein the first cavity and the second cavity are generated by means of a time-controlled etching process, wherein the etching rate varies for process-related reasons so that the structured cavities each comprises different aspect ratios, leading to the back-bias magnets each comprising different magnetic field characteristics,
the method further comprising:
providing a compensation circuit configured to drive the magnetic field sensor chip such that measurement deviations caused by the process-related different magnetic field characteristics are compensated.

13. Method according to claim 1, further comprising:
arranging a multitude of magnetic field sensors on the first substrate surface and generating a multitude of integrated back-bias magnets in a corresponding multitude of structured cavities,
wherein at least one integrated back-bias magnet is assigned to each magnetic field sensor.

14. Method according to claim 1,
wherein the method is carried out on the wafer level, and the substrate provided is a wafer, and wherein the magnetic field sensor chip is acquired from the wafer by dicing.

15. Magnetic field sensor chip with an integrated back-bias magnet manufactured by using a method according to claim 1.
